(19) United States
(12) Patent Application Publication
(10) Pub. No.: US 2013/0187680 A1
(43) Pub. Date: Jul. 25, 2013

(54) Complementary Logic Device Comprising Metal-to-Insulator Transition Material

(71) Applicants: IMEC VZW, Leuven (BE); Katholieke Universiteit Leuven, K.U. LEUVEN R&D, Leuven (BE)

(72) Inventors: Koen Martens, Leuven (BE); Iuliana Radu, Leuven (BE)

(73) Assignees: Katholieke Universiteit Leuven, K.U. LEUVEN R&D, Leuven (BE); IMEC VZW, Leuven (BE)

(21) Appl. No.: 13/744,625

(22) Filed: Jan. 18, 2013

Related U.S. Application Data
(60) Provisional application No. 61/588,946, filed on Jan. 20, 2012.

(51) Int. Cl. H03K 19/20

(52) U.S. Cl. CPC H03K 19/20
USPC 326/104

(57) ABSTRACT

A complementary logic technology is disclosed whereby a logic gate comprises at least two metal-to-insulator transition (MIT) elements and at least two thermoelectric elements, each MIT element being thermally coupled to a corresponding thermoelectric element. In logic gates, each electric signal at an input terminal of a logic gate is first converted into two complementary thermal signals, and these thermal signals in turn determine the status of the output terminal of the logic gate, thereby generating an electrical output signal inverse to the electrical input signal or an output signal which is a Boolean operation on input signals. The parallel connection(s) of thermoelectric elements of the logic gate is used to create corresponding thermal signals for each electrical input signal. The MIT elements of the logic gate are then arranged to, in response to the associated thermal signals, execute a Boolean operation.

### CROSS REFERENCE TO RELATED APPLICATIONS

Pursuant to the provisions of 35 U.S.C. §119(e), this application claims priority to U.S. Provisional Patent Application Ser. No. 61/588,946, which was filed Jan. 20, 2012. The entire contents of U.S. Provisional Patent Application Ser. No. 61/588,946 are incorporated herein by reference.

### BACKGROUND

The contemporary dominant form of logic technology is CMOS. Each input of a CMOS logic gate is coupled to an nMOSFET and a pMOSFET. Each transistor comprises a semiconductor region capacitively coupled to an electrode, known as gate electrode. When this gate electrode is biased by a signal applied to input of the CMOS logic device, the conductivity of the semiconductor region is modulated. The polarity of the voltage required to induce such a conductivity change depends on whether it relates to an nMOSFET or pMOSFET. The semiconductor region, known as channel, is further electrically connected to two electrodes, respectively known as source and drain, for transferring charge to and from this channel.

CMOS technology is continuously scaled down. However, at some point during scaling down, band-to-band tunneling effects in the channel will become a major hurdle. Source and drain electrodes of the transistor cannot be moved closer indefinitely without at some point inducing large leakage currents between them. Furthermore, scaling down will become a problem as adequate electrostatic control of the gate electrode over the channel region needs to be maintained. This gate electrode control is the incentive for modifying the gate architecture resulting in, e.g., finFETS and/or for introducing new materials, such as high-k dielectrics for the dielectric MOS capacitor dielectric and metal for the gate electrode. The use of high-k dielectric is also motivated by gate leakage issues in SiO₂ when the thickness thereof is reduced. Further issues are due to process-induced variability, the need to maintain or increase performance, and the need to reduce the power supply voltage.

At some point CMOS logic technology itself might prove to become less optimal. An alternative complementary logic technology is disclosed capable of scaling down and offering one or more advantages over CMOS logic technology. The proposed logic can also serve other application domains.

### SUMMARY

A complementary logic technology is disclosed whereby a logic gate comprises at least two metal-to-insulator transition (MIT) elements and at least two thermoelectric elements, one MIT element being thermally coupled to one thermoelectric element whereby the MIT elements are electrically isolated from the thermoelectric elements.

In one example, a complementary logic gate is disclosed comprising one input terminal for receiving an electrical input signal, an output terminal for outputting an electrical output signal, a first and a second thermoelectric element configured in parallel between ground and the input terminal whereby the thermoelectric elements are selected to generate complementary thermal signals in response to a same electrical input signal, a first and a second metal-to-insulator transition element configured between the output terminal and respectively a positive power supply line and a negative power supply line and electrically isolated from any thermoelectric element, the first transition element being thermally connected to the first thermoelectric element and the second transition element being thermally connected to the second thermoelectric element.

In another example, a complementary logic inverter gate is disclosed consisting of one input terminal for receiving an electrical input signal, one output terminal for outputting an electrical output signal, a first and a second thermoelectric element configured in parallel between ground and the input terminal whereby the thermoelectric elements are selected to generate complementary thermal signals in response to a same electrical input signal, a first metal-to-insulator transition element configured between the output terminal and a positive power supply line and thermally connected to the first thermoelectric element, a second metal-to-insulator transition element configured between the output terminal and a negative power supply line and thermally connected to the second thermoelectric element, whereby all MIT elements are electrically isolated from any thermoelectric element. Preferably, the MIT element connected to the negative power supply line is heated when biased with a positive voltage thereby reducing its electrical resistance, while the MIT element connected to the positive power supply line is cooled when biased with a positive voltage thereby increasing its electrical resistance.

In another example, a complementary logic NAND gate is disclosed comprising at least a first and a second input terminal, each input terminal being configured for receiving an electrical input signal and an output terminal for outputting an electrical output signal, each input terminal being connected to a parallel configuration towards ground of a first and a second thermoelectric element whereby the thermoelectric elements are selected to generate complementary thermal signals in response to a same electrical input signal, a parallel configuration of metal-to-insulator transition elements configured between the output terminal and a positive power supply line the number of transition elements in parallel equaling the number of input terminals whereby each one of the parallel transition elements is thermally connected to only one of the first thermoelectric elements, a series configuration of metal-to-insulator transition elements configured between the output terminal and a negative power supply line the number of transition elements in series equaling the number of input terminals whereby each one of the serial transition elements is thermally connected to only one of the second thermoelectric elements and whereby all transition elements are electrically isolated from any thermoelectric element.

In another example, a complementary logic NOR gate is disclosed comprising at least a first and a second input terminal, each input terminal being configured for receiving an electrical input signal and an output terminal for outputting an electrical output signal, each input terminal being connected to a parallel configuration towards ground of a first and a second thermoelectric element whereby the thermoelectric elements are selected to generate complementary thermal signals in response to a same electrical input signal, a serial configuration of metal-to-insulator transition elements configured between the output terminal and a positive power supply line the number of transition elements in series equaling the number of input terminals whereby each one of the serial transition elements is thermally connected to only one of the first thermoelectric elements, a parallel configuration of metal-to-insulator transition elements configured between the output terminal and a negative power supply line the number of transition elements in parallel equaling the number of input terminals whereby each one of the parallel transition elements is thermally connected to only one of the second thermoelectric elements.

In another example, a complementary logic gate is disclosed comprising at least two metal-to-insulator transition (MIT) elements and at least two thermoelectric elements configured in parallel between ground and an input terminal whereby one MIT element is thermally coupled to one thermoelectric element, an electric signal at an input terminal of the logic gate is first converted into two complementary thermal signals, and these thermal signals in turn determine the status of the output terminal of the logic gate, thereby generating an electrical output signal inverse to the electrical input signal or another Boolean operation on input signals. The parallel configuration of thermoelectric elements of the logic gate generates complementary thermal signals for each electrical input signal. The MIT elements of the complementary logic gate are then thermally connected in such a way to the MIT elements to execute the Boolean operation of the complementary logic gate.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

The drawings are intended to illustrate some aspects and embodiments of the present disclosure. The drawings described are only schematic and are non-limiting.

FIG. 1 shows a diagram of the resistance (R) versus temperature (T) characteristic of an MIT element indicating the off resistance (R_{off}), on resistance (Rₒₙ), and transition temperatures when cooling (T_{tH}) and when heating (T_{tL}).

FIG. 2 shows a circuit diagram of a logic inverter comprising two thermoelectric elements, e.g., a Peltier element, and two MIT elements, whereby one MIT element is coupled to one thermoelectric element.

FIG. 3 shows a circuit diagram of a NAND logic gate comprising MIT elements and thermoelectric elements, e.g., Peltier elements, which are thermally coupled.

FIG. 4 shows a circuit diagram of a NOR logic gate comprising MIT elements and thermoelectric elements, e.g., Peltier components, which are thermally coupled.

FIGS. 5a-c schematically illustrate implementations of a logic inverter as shown in FIG. 2.

FIGS. 6a-c schematically illustrate the operation of a logic inverter as shown in FIG. 5a when a positive voltage pulse is applied to the thermoelectric elements: a) situation prior to the application of the voltage pulse; b) positive input voltage applied, which causes cooling in the upper thermoelectric element and heating in the lower thermoelectric element; c) situation after the voltage pulse has been applied.

FIGS. 7a-c schematically illustrate the operation of a logic inventor as shown in FIG. 5a when a negative voltage pulse is applied: a) situation prior to the application of the voltage pulse; b) negative input voltage applied, which causes heating in the upper thermoelectric element and cooling in the lower thermoelectric element; c) situation after the voltage pulse has been applied.

### DETAILED DESCRIPTION

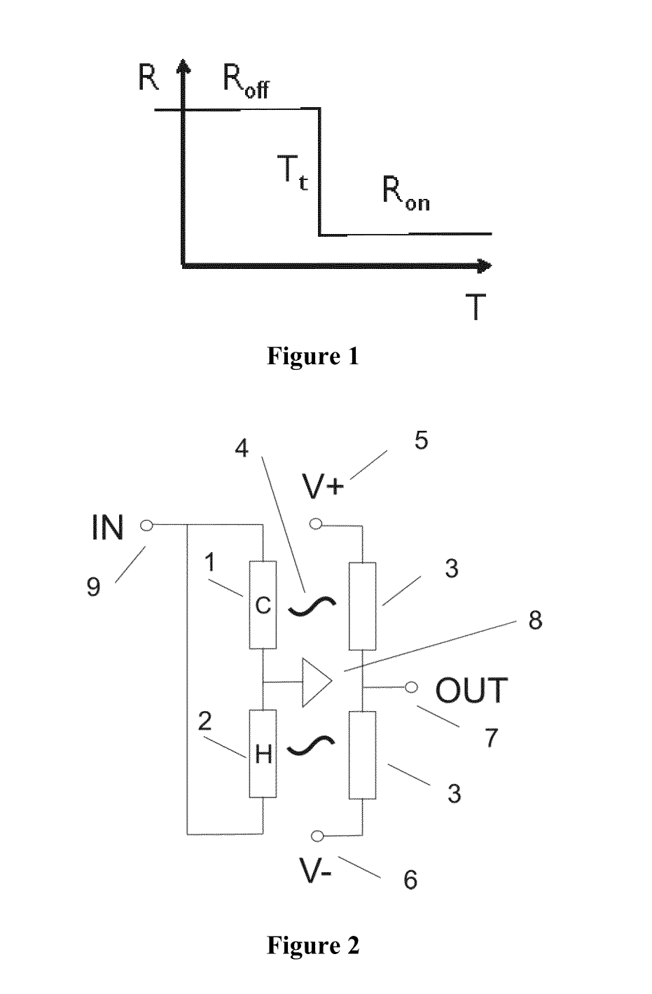

A typical Metal-to-Insulator-Transition material (MIT) is VO₂. Such a MIT material shows a large change in its electronic structure and conductivity under the influence of external factors such as pressure or temperature. Sometimes the electronic change is associated with a small reversible shift in atomic lattice position promising compatibility with sub-10 nm scalability. Due to a hysteresis effect, the MIT phase switches between a low electrical conductive state R_{off} and a high electrical conductive state Rₒₙ, as illustrated in FIG. 1, when heating or cooling, respectively, above and below a transition temperature Tₜ.

A complementary logic technology is disclosed whereby a logic gate comprises at least two metal-to-insulator transition (MIT) elements and at least two thermoelectric elements, each MIT element being thermally coupled to a corresponding thermoelectric element. Each electric signal at an input terminal of a logic gate is first converted into two complementary thermal signals, and these thermal signals in turn determine the status of the output terminal of the logic gate, thereby generating an electrical output signal inverse to the electrical input signal or combination of input signals.

A MIT material shows a phase transition at a given temperature, the transition temperature Tₜ as illustrated in FIG. 1. The transition from one electrical conductive state to another electrical conductive state occurs when the temperature of the MIT material is changed. The MIT material has two relevant phases, which are here called the low and high temperature phase or the high resistance R_{off} and low resistance Rₒₙ phase, respectively. An example of such an MIT material is vanadium dioxide or doped vanadium dioxide. Within the logic gate, this MIT material is contained between two electrodes or terminals, and constitutes a two-terminal element with a temperature dependent resistance, whose operation is schematically illustrated by FIG. 1. Optionally, a barrier layer can be added to this MIT element (3) to change properties, such as the electrical or thermal resistance of the MIT element.

The thermoelectric element (1, 2) can generate a heat flow such that the thermoelectric element heats or cools objects (3) thermally linked to it (1, 2). A thermoelectric element (1, 2) contains two terminals for respectively providing current through the element. The term “thermoelectric effect” refers to the direct conversion of a temperature difference to an electric voltage difference and vice-versa. When there is a different temperature between the terminals of a thermoelectric element (1, 2), an electric voltage difference between these terminals is created. When an electrical voltage difference is applied between the terminals of the thermoelectric element (1, 2), a temperature difference is created between these terminals. This effect is here used to change the temperature of objects that are thermally coupled to the thermoelectric element (1, 2). Whether the thermoelectric element is heating or cooling, is determined by the polarity of the electric voltage applied over the thermoelectric element. Hence, thermoelectric elements are efficient temperature controllers. This thermoelectric effect is also referred to as the Peltier or Peltier-Seebeck effect. This thermoelectric element (1, 2) can be made of a material such as BiTe, PbTe, SiGe, some silicides and so on of p-type and/or n-type nature or other thermoelectric materials or a combination thereof.

MIT elements (3) are combined with and thermally coupled to thermoelectric elements, such as Peltier elements (1, 2), to construct logic gates. Two types of thermoelectric elements (1, 2) are used in each logic gate. A first type of thermoelectric element (1) cools its thermally linked MIT element (3) when biased positively, or at least does not heat it above the transition temperature T. This type of thermoelectric elements is referred to as C-type element (1). A second type of thermoelectric element (2) heats its thermally linked MIT element (3) when biased positively. This type of thermoelectric element is referred to as H-type element (1). As these thermoelectric elements (1, 2) have an opposite thermal response, i.e., cools or heats, when applying the same electrical signal to them, they can be considered as complementary devices.

As illustrated by FIG. 2, a logic inverter is constructed using two MIT elements (3), a C-type thermoelectric element (1) and an H-type thermoelectric element (2), arranged in a parallel configuration between the input (9) and ground terminal (8). The C-type thermoelectric element (1) is thermally coupled (4) to one MIT element (3), while the H-type thermoelectric element (2) is thermally coupled (4) to the other MIT element (3). By making use of complementary thermoelectric elements (1, 2), one of these elements (1, 2) cools while the other (2, 1) heats when applying the same electrical signal to both elements (1, 2). In a logic inverter, this complementary effect is exploited to invert the incoming signal applied to the logic gate.

In the logic inverter of FIG. 2, each of the complementary two-terminal thermoelectric elements (1, 2) has one terminal connected to ground (8) and the other terminal connected to the input terminal (9) of the logic inverter. A thermoelectric element (1) is thermally linked (4) to, but electrically isolated from, one MIT element (3). There is hence a thermally well-conducting path from that thermoelectric element (1) to its associated MIT element (3) allowing that thermoelectric element (1) to efficiently cool or heat its associated MIT element (3). This MIT element (3) is with one terminal hooked up electrically to a positive voltage rail (5, V+). The complementary thermoelectric element (2) is thermally linked (4) to, but electrically isolated from, the other MIT element (3), which is with one terminal hooked up electrically to the negative voltage rail (6, V−). Each MIT element (3) has one terminal hooked up electrically to the output (7) of the logic inverter.

When applying a positive bias to the input terminal (9) of the logic inverter, the MIT element (3) connected to the positive voltage rail (5) is cooled and kept in the low temperature, high resistance state R_{off}. The temperature of its associated thermoelectric element (1) is kept below the transition temperature Tₜ when applying a positive voltage signal, thereby maintaining the thermally linked MIT element (3) in its high resistive state R_{off}. The other MIT element (3), connected to the negative or lower voltage rail (6), is heated by its thermally linked thermoelectric element (2) when the positive input voltage is applied. This other MIT element (3) switches to the high temperature state with low resistance Rₒₙ, thereby hooking up the output (7) of the inverter to the negative voltage rail (6, V−). Hence, the output (7) of the logic inverter generates an electric signal (OUT) being the inverse of the input signal (IN). The opposite occurs when applying a negative bias to the input terminal (9) of the logic inverter. Hence, a logic gate according to this disclosure will operate with a negative or a positive input signal, preferably in the voltage range of 5 mV to 5V in absolute value. Higher voltages can potentially also be used for non-CMOS electronics applications.

As Peltier elements are current driven, this thermally operated logic inverter, illustrated by FIG. 2, processes current pulses instead of voltages as was the case in regular CMOS logic technology. When no signal is processed, the inverter and its input (9) and output (8) terminals are in a high impedance state R_{off} avoiding static electric power dissipation. After a current pulse originating from a previous logic gate has been applied at the input terminal (9) of this logic inverter, its input terminal (9) becomes highly impedant because the MIT elements (3) of the previous logic gate change back to their high impedance state R_{off}. Also, the output terminal (7) of this logic gate becomes highly impedant, because its MIT elements (3) will return to their equilibrium low temperature high resistive state R_{off} as well. As each input and output terminal in a chain of logic inverters will return to a high impedance steady state, a current pulse is propagated through the logic system while the ‘sleeping’ or inactive inverters are in the high impedance state. The current driven nature of this logic system reduces the charging of parasitic capacitances and associated losses because low voltages can be used.

The pulsed current nature of the logic operation of the disclosed logic gates requires the low resistance state to be the stable state in the operating temperature range. Hence, the transition temperature Tₜ of the MIT material should be above the upper temperature of the intended operating temperature range of the integrated circuit. This also means that the function of the cooling Peltier element (C) is in first instance to avoid heating the linked MIT element above its transition temperature Tₜ, which relaxes the requirements for the Peltier element. The operating temperature range, i.e., the temperature at which the integrated device is in steady state can be enlarged by increasing the transition temperature by engineering the MIT material. This tuning of the transition temperatures can, e.g., be done by doping the MIT material.

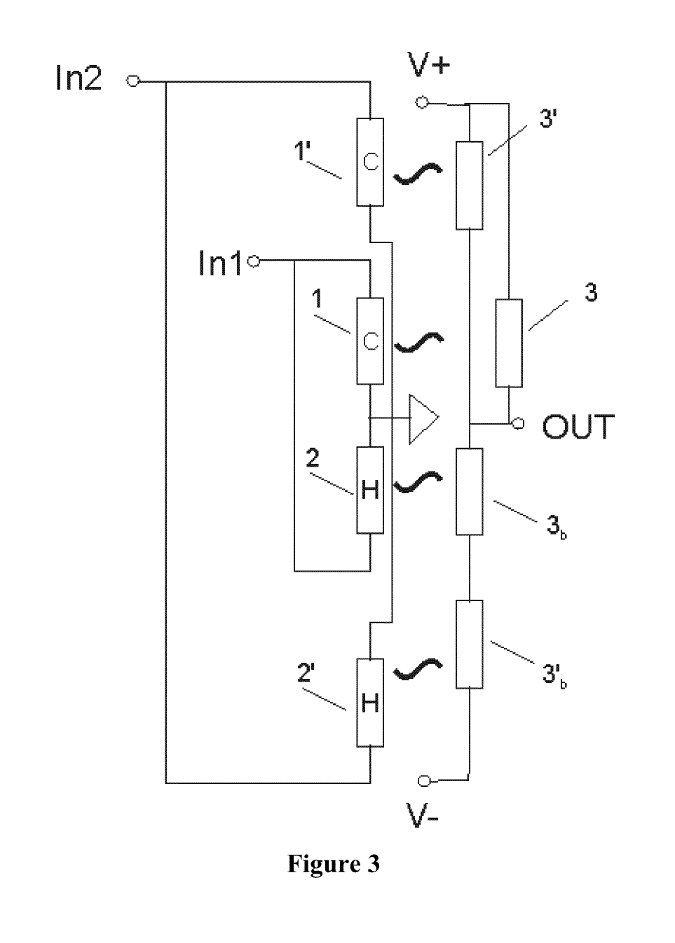

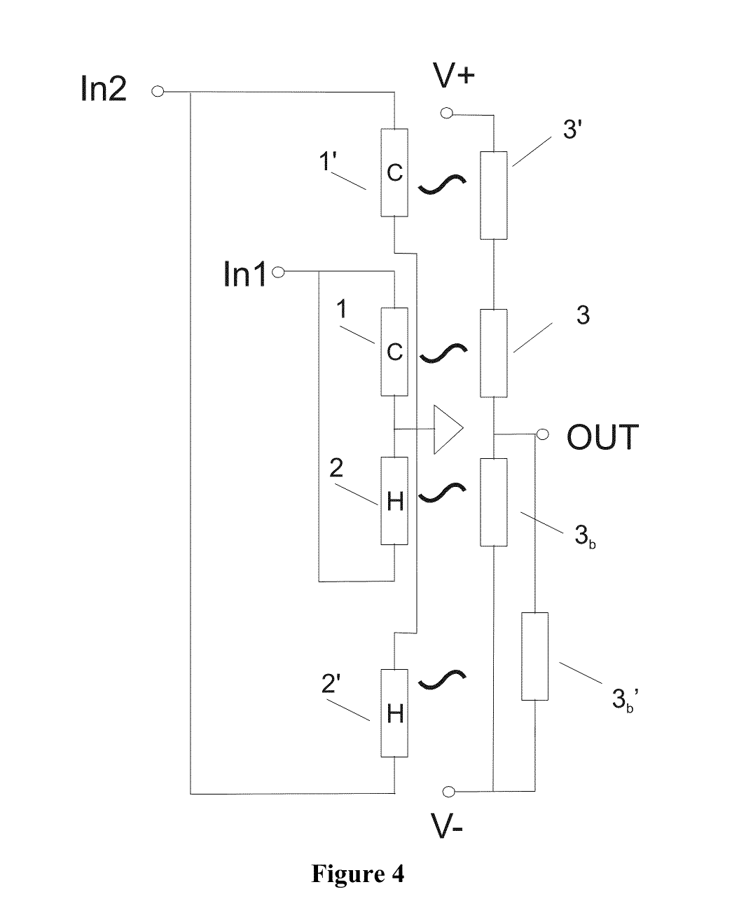

As in CMOS logic, other logic gates such as NAND and NOR gates can be constructed as illustrated by FIGS. 3 and 4, respectively.

FIG. 3 shows a NAND logic gate. When both inputs In2 and In1 are positively biased, the output OUT will be negatively biased. Each input signal creates a pair of complementary thermal signals when applied to each of the parallel connections of C-type (1, 1′) and H-type (2, 2′) thermoelectric elements. The associated MIT elements (3, 3′) of the two C-type thermoelectric elements (1, 1′) are configured in parallel between the positive voltage rail (5, V+) and the output terminal (7). The associated MIT elements (3b, 3b′) of the two H-type thermoelectric elements (2, 2′) are configured in series between the negative voltage rail (6, V−) and the output terminal (7). As these two bottom MIT elements (3b, 3b′) are put in series, both MIT elements need to be heated in order to hook up the output terminal (7) to the negative voltage rail (6, V−), thereby, generating an output signal being a Boolean NAND operation of both input signals. The MIT elements are arranged like the transistors of a CMOS logic NAND gate in order to execute the Boolean NAND operation on the thermal signals, more precisely on the electrical impedance of the associated MIT elements.

Table 1 lists the response of the thermoelectric elements and the associated MIT elements to the electrical input signals In1, In2 applied to respectively one of the input terminals of the NAND gate. A logic ‘1’ refers to a current flowing into the input terminal towards ground, while a logic ‘0’ refers to a current flowing from ground out of the input terminal. The thermoelectric elements can either cool or heat in response of this current signal, while the impedance of the associated MIT element either remains high (OFF) when being cooled or drops (ON) when being heated.

TABLE 1
truth table for a complementary NAND gate

| | | | | | | MIT elements: | | | | |
|---|---|---|---|---|---|---|---|---|---|---|
| | | Thermoelectric | | | | high (OFF) | | | | |
| | | elements: | | | | or low (ON) | | | | |
| input | | cooling or heating | | | | impedance | | | | Out- |
| In1 | In2 | 1 | 2 | 1′ | 2′ | 3 | 3_{b} | 3′ | 3_{b}′ | put |
| 0 | 0 | heat | cool | heat | cool | ON | OFF | ON | OFF | 1 |
| 1 | 0 | cool | heat | heat | cool | OFF | ON | OFF | ON | 1 |
| 0 | 1 | heat | cool | cool | heat | ON | OFF | OFF | OFF | 1 |
| 1 | 1 | cool | heat | cool | heat | OFF | ON | OFF | ON | 0 |

FIG. 4 shows a NOR logic gate according to this disclosure. If at least one of both inputs In2 and In1 is positively biased, the output OUT will be negatively biased. Each input signal creates a pair of complementary thermal signals when applied to each of the parallel connections of C-type (1, 1′) and H-type (2, 2′) thermoelectric elements. The associated MIT elements (3, 3′) of the two C-type thermoelectric elements (1, 1′) are configured in series between the positive voltage rail (5, V+) and the output terminal (7). The associated MIT elements (3b, 3b′) of the two H-type thermoelectric elements (2, 2′) are configured in parallel between the negative voltage rail (6, V−) and the output terminal (7). As these two bottom MIT elements (3b, 3b′) are put in parallel, only one MIT element (3b, 3b′) needs to be heated in order to hook up the output terminal (7) to the negative voltage rail (6, V−). However, both top MIT (3, 3′) elements need to be heated in order to hook-up the output terminal (7) to the positive voltage rail (5, V+), thereby, generating an output signal being the Boolean NOR operation of both input signals. For the NOR case only when both inputs are negatively biased does one expect a positively biased output. The MIT elements are arranged like the transistors of a CMOS logic NOR gate in order to execute the Boolean NOR operation on the input signals.

Table 2 lists the response of the thermoelectric elements and the associated MIT elements to the electrical input signals In1, In2 applied to respectively one of the input terminals of the NOR gate. A logic ‘1’ refers to a current flowing into the input terminal towards ground, while a logic ‘0’ refers to a current flowing from ground out of the input terminal. The thermoelectric elements can either cool (C) or heat (H) in response of this current signal, while the impedance of the associated MIT element either remains high (OFF) when being cooled or drops (ON) when being heated.

TABLE 2
truth table for a complementary NOR gate

| | | | | | | MIT elements: | | | | |
|---|---|---|---|---|---|---|---|---|---|---|
| | | Thermoelectric | | | | high (OFF) | | | | |
| | | elements: | | | | or low (ON) | | | | |
| input | | cooling or heating | | | | impedance | | | | Out- |
| In1 | In2 | 1 | 2 | 1′ | 2′ | 3 | 3_{b} | 3′ | 3_{b}′ | put |
| 0 | 0 | heat | cool | heat | cool | ON | OFF | ON | OFF | 1 |
| 1 | 0 | cool | heat | heat | cool | OFF | ON | OFF | ON | 0 |
| 0 | 1 | heat | cool | cool | heat | ON | OFF | OFF | OFF | 0 |
| 1 | 1 | cool | heat | cool | heat | OFF | ON | OFF | ON | 0 |

As can be noticed from the operation of the NAND and NOR gate illustrated by FIGS. 3 and 4 respectively, the parallel connection(s) of thermoelectric elements of the logic gate is used to create corresponding thermal signals for each electrical input signal. The MIT elements of the logic gate are then arranged to, in response to the associated thermal signals, execute a Boolean operation. In CMOS complementary logic, the input signal is capacitively coupled to a circuit executing the Boolean operation, whereby the complementary aspect is obtained by using transistors of opposite polarity type, i.e., n-type or p-type MOSFETs. In the complementary logic disclosed, the input is signal is thermally coupled to a circuit executing the Boolean operation, whereby the complementary aspect is obtained by creating complementary thermal signals.

### EXAMPLES

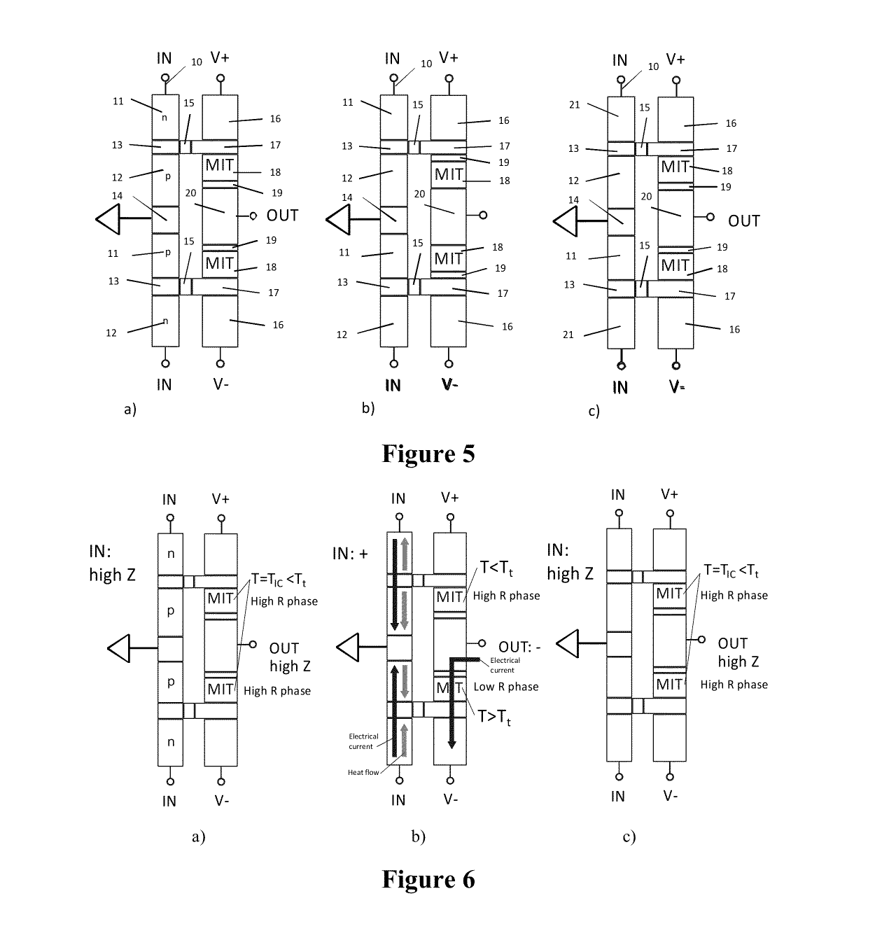

Examples of how the logic inverter disclosed in FIG. 2 can be implemented shown in FIGS. 5a-c.

In FIG. 5a, the upper Peltier element being a C-type consists of a combination of an n-type Peltier material (11) and a p-type Peltier material (12). A junction conductor (13) separates the two Peltier materials (11, 12). The junction conductor (13) is formed of a good thermal and electrical conductive material such as Al, Cu. The lower Peltier element being an H-type consists of a combination a p-type (12) and n-type Peltier material (11) and a similar junction conductor (13) separating both Peltier materials (11, 12).

Both Peltier elements (C, H) are connected to the ground via the common ground interconnect (14), thereby forming a parallel connection between the ground (14) and the input terminal (10). The ground interconnect (14) is made of a good electrical and thermally conductive material. The thermal link (4) between a Peltier element (C, H) and its associated MIT element (3) is formed by a series connection of two conductors, both formed in a thermally and electrically conductive material, connected by an electrically insulating but thermally conductive material.

As shown in FIG. 5a the junction conductor (13) extends towards the MIT element, contacts an electrically isolating thermal bridge (15) made out of a dielectric with good thermal conductivity, such as Al₂O₃ or HfO₂. This thermal bridge conveys the thermal signal to a junction conductor (17) leading to the MIT element. This junction conductor (17) is also made out of a good electrical and thermally conductive material. The MIT element comprises a layer of an MIT material (18) and an optional barrier layer (19) connected to the output terminal (20). The MIT element is also connected electrically to a voltage supply rail by an interconnect (16). The interconnect (16) is made out of a material with high electrical conductivity and low thermal conductance such as Ti, TiN, GeSbTe, in order to limit heat leaking away from the MIT element. The other terminal of the MIT element is connected to the output interconnect (20), also made of a material with high electrical conductivity, but low thermal conductivity.

The implementation schematically shown in FIG. 5b only differs from the one in FIG. 5a in the position of the barrier layer (19). In FIG. 5b, the barrier layer (19) is located in between the MIT element (3) and the junction conductor (17). Other spatial configurations are possible with for example the MIT element (3) in between the junction conductor (19) and the voltage supply rail (V+).

The implementation shown in FIG. 5c only differs from the one in FIG. 5b in that simplified Peltier elements are used. Each Peltier element consists of a combination of one leg formed of either an n-type material (12) or a p-type material (11) while the other leg of the Peltier element is formed by an input interconnect (21) made out of a material with high electrical conductivity, but low thermal conductivity.

In FIGS. 6a-c, the operation of the logic inverter of FIG. 5a is shown schematically for a positive input voltage or a current running into the inverter towards ground. The situation before the pulse is applied is shown in FIG. 6a. The inverter is in a high impedance state and the logic device is at a temperature T_{IC} below the transition temperature Tₜ. When an electrical pulse is applied, as shown in FIG. 6b, the current running through the Peltier elements causes the upper MIT element to cool down or to stay below the transition temperature Tₜ, while the lower MIT element heats up above the transition temperature Tₜ. The output node is now connected electrically to the negative voltage supply rail and draws current to drive the next logic gate. Once the logic inverter is returned to steady state, the output node is in a high impedance state as the temperature of both MIT elements is below the transition temperature Tₜ as shown in FIG. 6c.

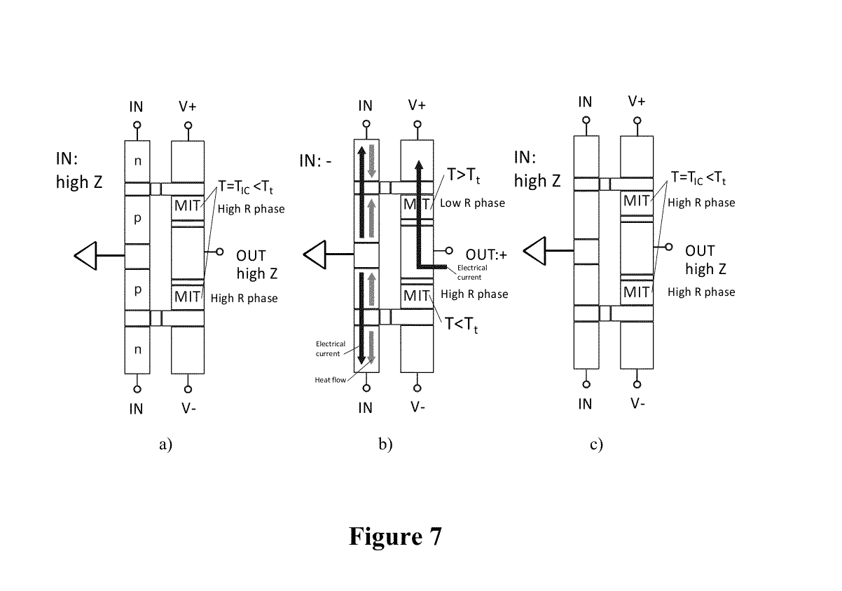

In FIGS. 7a-c, the operation of the logic inverter shown in FIG. 5a is illustrated schematically for a negative input voltage or a current running from ground into the inverter. The situation before the pulse is applied is shown in FIG. 7a. The inverter is in a high impedance state and the logic device is at a temperature T_{IC} below the transition temperature Tₜ. When an electrical pulse is applied, as shown in FIG. 7b, the current running from ground into the Peltier elements causes heats the upper MIT element to be heated above the transition temperature Tₜ, while the lower MIT element is cooled down or stays below the transition temperature Tₜ. The output node is now connected electrically to the positive voltage supply rail and draws current to drive the next logic gate. Once the logic inverter is returned to steady state, the output node is in a high impedance state as the temperature of both MIT elements is below the transition temperature Tₜ as shown in FIG. 7c.

It is intended that the foregoing detailed description be regarded as illustrative rather than limiting and that it is understood that the following claims including all equivalents are intended to define the scope of the invention. The claims should not be read as limited to the described order or elements unless stated to that effect. Therefore, all embodiments that come within the scope and spirit of the following claims and equivalents thereto are claimed as the invention.

1. A complementary logic technology whereby a logic gate comprises:
at least two metal-to-insulator transition (MIT) elements; and
at least two thermoelectric elements, one MIT element being thermally coupled to one thermoelectric element, wherein the MIT elements are electrically isolated from the thermoelectric elements.
